(19) United States
(12) Patent Application Publication
(10) Pub. No.: US 2005/0121321 A1
(43) Pub. Date: Jun. 9, 2005

(54) Ignition device

(76) Inventor: Andreas Schutze, Malibu, CA (US)

Correspondence Address: NOTARO AND MICHALOS, 100 DUTCH HILL ROAD, SUITE 110, ORANGEBURG, NY, 10962-2100, US

(21) Appl. No.: 10/991,047

(22) Filed: Nov. 17, 2004

(30) Foreign Application Priority Data
Nov. 18, 2003 (CH) 01971/03

(51) Int. Cl. C23C 14/32

(52) U.S. Cl. 204/298.41; 204/192.38

(57) ABSTRACT

Ignition device for igniting a high-current discharge of an electric arc vaporizer in a vacuum coating installation with a target (9) with target surface (20), a counterelectrode (6) as well as an arc supply (4) for maintaining an arc discharge between target (9) and counterelectrode (6), the ignition device (1) comprising an ignition finger (1′), switchable to a different ignition potentials with respect to the target (9), with a tip (10) and a switch (2), the tip (10) being comprised of a material with a high melting point and in continuous electric contact with the target surface (20).

The invention relates to an ignition device for igniting a high-current discharge of an electric arc vaporizer in a vacuum coating installation according to the preamble of claim 1.

An arc vaporizer as described above, also referred to as arc or spark source, is employed for treating workpieces in high vacuum, in particular for plasma etching and/or for coating.

U.S. Pat. No. 3,783,231, U.S. Pat. No. 4,448,799 and U.S. Pat. No. 4,622,452 disclose various mechanical ignition fingers, in which the ignition of the arc discharge takes place by briefly placing the ignition finger onto the surface of the target, and, when withdrawing the ignition tip, a breaking spark is produced, which generates a sufficient number of electric charge carriers.

The disadvantage of such a device, currently utilized in many vacuum coating installations, is that at each arc source mechanically moved parts are disposed, which require a not inconsiderable adjustment and readjustment complexity as well as conventionally require dynamically loaded vacuum leadthroughs, which are frequently susceptible to failure. Furthermore, strong magnetic fields, such are frequently used in vacuum coating processes, can hinder the movement of the ignition finger. Due to the necessary robustness of the mechanical system, such devices are also conventionally implemented in a relatively large form, which necessitates an additional space requirement in the vacuum chamber.

EP 0 211 413 discloses another ignition mechanism. In this patent between the target surface (cathode) and the anode a ceramic insulator is disposed coated with a thin layer of electrically conductive material. After applying an ignition voltage between the cathode and the anode, the entire current flows over this thin conducting layer, whereby it vaporizes in one burst and charge carriers are liberated which make possible the igniting of the arc. After the coating process is switched off, a thin layer remains on the insulator, which allows the repeat ignition of the arc. Of disadvantage of such an ignition device is that it can only be employed in the production of layers which are sufficiently conductive.

The invention addresses the problem of providing an ignition device for an electric arc vaporizer which avoids the disadvantages of prior art.

This problem is solved through the characteristics according to the invention in the characterizing clause of claim 1.

The ignition finger is installed such that the tip is permanently in contact with the target surface, which permits implementing the ignition device in a highly simple manner and without complex movable parts. In spite of the mechanically simple solution, in which a periodic readjustment of mechanical components is no longer required, the reliable ignition of the spark source is surprisingly successful even if, for example, high-ohmic layers are being deposited.

Moreover, in the case of such an ignition device no susceptibility to failure could be detected even in the presence of strong magnetic fields.

In the following the invention will be explained in further detail in conjunction with Figures illustrating several embodiment examples. In the drawing depict:

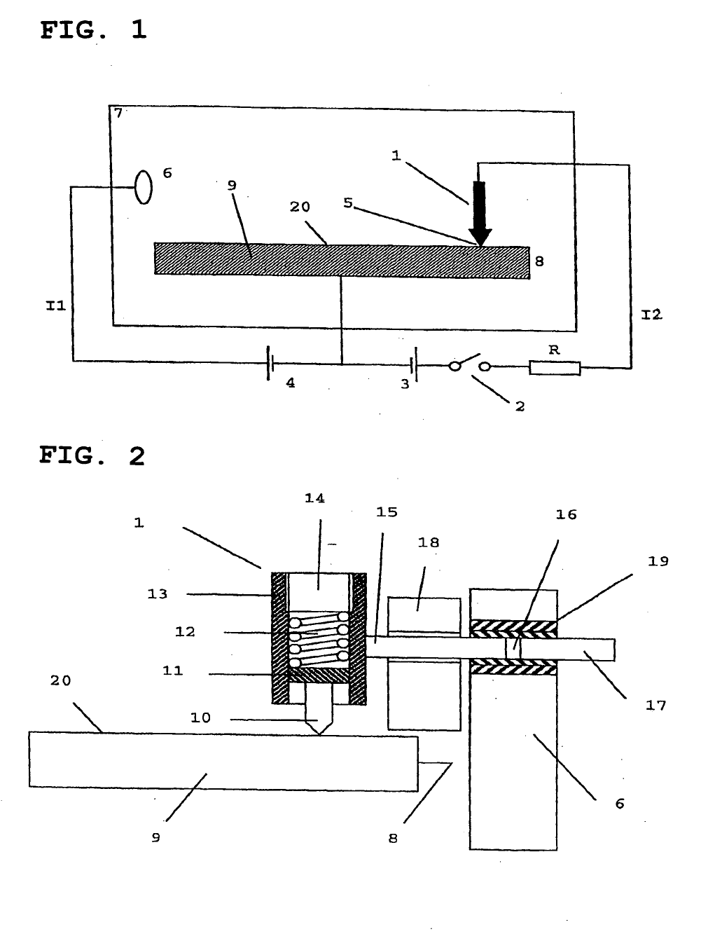

FIG. 1 section through a vacuum chamber with arc source and ignition device, and

FIG. 2 ignition device.

FIG. 1 shows schematically the functional principle of an arc source installed in a vacuum chamber 7 with an ignition device 1 according to the invention. In contrast to the above described prior art, the ignition finger is continuously in electrically conducting contact on the target surface even during the operation of the spark source. In order to ensure the continuous electrical contact in spite of the high mechanical stresses occurring during the operation due to temperature, and therewith to ensure a reliable ignition process, the tip must be pressed against the target surface, for example via a spring mechanism.

To apply the ignition potential, a switch 2 is closed, and an electric current flows supplied, in this case, from an ignition generator 3, over a circuit I2. If a sufficiently high voltage is applied, due to the relatively high contact resistance between the ignition tip 10 and the target 9, local melting and vaporization of the target surface 20 occurs at ignition point 5. Additionally, during the ignition of the arc source, presumably through the tip effect occurring at high energy density and/or through microsparks, ionization of the metal vapor occurs, whereby the source circuit 11 fed from the generator of the arc supply 4, between the target 9, here connected cathodically, and the anode 6 is closed through the discharge plasma of the arc source.

The switch 2 should be selected such that switch-on times of a second or less are possible in order to avoid the thermal overloading of the ignition device 1. During the tests the arc source could be ignited reliably at an ignition duration t_{zünd} between 0.05 to 1 s.

The application of the ignition potential can fundamentally also take place in simpler manner than through an additional ignition generator 3, which, however, offers the advantage of a variable adjustable voltage. For example, in circuit I2, it is possible to switch to the zero potential or to the positive output signal of the arc supply 4, which, as shown in FIG. 1, can also be connected to the anode 6, instead of the ignition generator 3. The setting of the desired ignition voltage can in this case take place via corresponding resistors R.

In preliminary tests, it was possible to generate the ignition of the arc at an ignition potential between +20 and +250 V relative to the cathode. For continuous tests the ignition potential was set between +100 and +180 V.

A further important point is the selection of a suitable material for the ignition finger 1′. Since the geometry of the ignition tip is to be approximately retained, in order to maintain the contact resistance to the target surface at a constant high level, it is important to vaporize the target surface and not the tip of the ignition finger. The material, of which at least the tip of the ignition finger must be comprised, must therefore have a melting point which is markedly higher, preferably by a few 100° C. than that of the target material and must not tend to form alloys with the target material at the ignition temperature. In order to permit universal applicability, the material should be thermally and mechanically stable at least at temperatures above 1000° C., but preferably still at temperatures of 2000° C. to 3000° C.; the material should consequently have a high melting point. In particular refractory metals are possible for use here, such as for example Zr, Nb, Mo, Ru, Rh, Pd, Hf, Ta, W, Re, Os, Ir, Pt or alloys of these metals or conductive compounds with nonmetals, such as for example tantalum or tungsten carbide.

Mechanically stabilized high carbon materials, such as for example carbon laminates, have also been found to be especially suitable.

In FIG. 2, a schematic example is shown of an embodiment in practice of an ignition device 1 according to the invention. It is comprised of a multi-part ignition finger 1′, fastened on a plug-in arm, as well as a plug connection 16, fastened on the anode and receiving the plug-in arm 15 under insulation, which connection is connected with the feed line 17. Therewith, for example for a target exchange, the ignition finger 1′ can simply be detached from the arc source in a short time.

In the present embodiment an industrial arc source, not further depicted in the drawing, with a target diameter of approximately 160 mm, such as is used in Balzers coating installations of type RCS or BAI 1200, was modified. In order to keep the space requirement of the ignition device 1 as low as possible, a bore was introduced into the encompassing anode 6 and the delimiting or confinement ring 18. In the bore of the anode 6 was mounted the plug connection 16, connected to the feed line 17, for receiving the plug-in arm 15. All parts 15, 16, 17 guided into the anode ring were electrically isolated from the anode 6 through an insulation 19.

The diameter of the bore of the confinement ring 18, electrically insulated with respect to the cathode, is laid out such that the gap between the outer diameter of the plug-in arm 15 and the inner diameter of the bore of the confinement ring 18 is minimally smaller than the dark space in conventional process conditions, i.e. approximately between 0.3 to 2 millimeters. Alternatively, here an insulation can also be provided, which, however, must withstand the high temperatures occurring here and the thermomechanical stresses resulting therefrom.

The ignition finger 1′ itself is structured in several parts. The housing 13 contains an advance device comprised of a spring 12 and a guide disk 11, whereby the tip 10 presses with substantially constant force onto the target surface 20. The spring 12 can additionally be preloaded through a setting screw 14.

In the structural form realized here the housing 13 was implemented cylindrically with a diameter of 12 mm and a height of 25 mm.

The ignition tip 10 with a diameter of approximately 3 mm was fabricated of a readily workable laminated carbon composite material by SGL-Carbon and sharpened at the end in contact on the target 9. It was subsequently plugged into the guide disk. The electric resistivity of the material at ambient temperature was between 20 and 30 Ohm×micrometer depending on the manufacture. In principle, the use of materials with lower or higher resistivity is also possible, since the contact resistance, as readily understood by a person skilled in the art, in the final analysis is the decisive factor is a result of the conductivity and the geometry of the tip. For high-carbon tips 10 a range of conductivity from 10 to 40 Ohm×micrometer can be covered.

Refractory metals indicate a lower resistivity of 0.04 to 0.12 Ohm×micrometer, which was the reason for selecting for such tests a narrower, to some extent needle-shaped, geometry of the tip 10.

For the spring 12, which during the operation of the target is located in the proximity of the plasma, the choice of the proper temperature-resistant material is essential. Especially suitable have been found to be springs 12 of chromium-nickel spring steel alloys, such as for example DIN X12CrNi177, 1.4310, with a spring rate between 0.2 to 3.0 N/mm, in particular between 0.5 to 1.0 N/mm.

The function tests were carried out with Ti, Cr or TiAlN targets. The electric resistance R was set in the range about 2 Ohms. At this value and at an ignition voltage about approximately 140 V briefly a current of approximately 70 A was measured. The switching mechanism was realized via a contactor, the closing and opening times being in the range of a few 100 milliseconds.

Under these conditions, an arc source could be ignited multiple times without encountering problems with an ignition device 1, as described in detail in connection with FIG. 2, under an Ar or N₂ atmosphere at pressures around 5×10⁻² mbar.

A further structural form of the ignition device can be attained if the ignition mechanism is disposed laterally, thus at the edge region 8 of target 9. However, here it is additionally necessary to ensure, for example through a magnetic guidance, that the spark is guided rapidly from the edge region 8 onto the surface 20 of the target in order to avoid damages of the insulating parts located between confinement or anode ring and target.

List of Reference Numbers

1 Ignition device
1′ Ignition finger
2 Switch
3 Ignition generator
4 Arc supply
5 Ignition point
6 Counterelectrode/anode
7 Vacuum chamber
8 Outer target region/edge region
9 Target
10 Tip
11 Guide disk
12 Spring
13 Housing
14 Setting screw
15 Plug-in arm
16 Plug connection
17 Supply line/feed line
18 Delimiting ring/confinement ring
19 Insulation
20 Target surface

1. Ignition device for an electric arc vaporizer with a target (9) with target surface (20), a counterelectrode (6) as well as an arc supply (4) for maintaining an arc discharge between target (9) and counterelectrode (6), the ignition device (1) comprising an ignition finger (1′), switchable to different ignition potentials with respect to the target (6), with a tip (10) and a switch (2), characterized in that the ignition finger (1′) is installed such that the tip (10) is continuously in contact with the target surface (20).

2. Ignition device as claimed in claim 1, characterized in that at least the tip 10) of the ignition finger (1′) has a markedly higher melting point than the target material.

3. Ignition device as claimed in claim 1, characterized in that the tip (10) of the ignition finger is a refractory metal.

4. Ignition device as claimed in claim 1, characterized in that the refractory metal comprises at least one of the elements, Zr, Nb, Mo, Ru, Rh, Pd, Hf, Ta, W, Re, Os, Ir, Pt or an alloy or compound of these elements.

5. Ignition device as claimed in claim 1, characterized in that at least the tip (10) of the ignition finger (1′) is comprised of a high-carbon material.

6. Ignition device as claimed in claim 5, characterized in that the high-carbon material is a carbon laminate.

7. Ignition device as claimed in claim 5, characterized in that the high-carbon material has an electric resistivity between 10 and 40 Ohm×micrometer, especially preferred between 20 to 30 Ohm×micrometer.

8. Ignition device as claimed in claim 1, characterized in that the switch (2) for the ignition duration t_{zünd} makes the tip (10) connectable to an ignition potential.

9. Ignition device as claimed in claim 8, characterized in that the switch (2) is switchable for an ignition duration t_{zünd}=0.05 to 1 s.

10. Ignition device as claimed in claim 1, characterized in that the ignition potential is the zero potential, the positive output signal of the arc supply (4) or a signal generated by an ignition generator (3).

11. Ignition device as claimed in claim 10, characterized in that the ignition potential is settable between +20 and +250 V, especially between +100 and +180 V, with respect to the cathode.

12. Ignition device as claimed in claim 1, characterized in that on the ignition finger (1′) an advance device is disposed in order to press the tip (10) at least during the ignition process with substantially constant force onto the target surface (20).

13. Ignition device as claimed in claim 12, characterized in that the advance device is a spring (12).

14. Ignition device as claimed in claim 13, characterized in that the spring (12) is comprised of a CrNi spring steel alloy.

15. Ignition device as claimed in claim 13, characterized in that the spring (12) has a spring constant of 0.2 to 3, preferably between 0.5 to 1 N/mm.

16. Electric arc vaporizer with an ignition device (1) as claimed in claim 1.

17. Method for the treatment, in particular for the plasma etching or coating, of a workpiece with an arc vaporizer as claimed in claim 16.
